(19) United States
(12) Patent Application Publication
(10) Pub. No.: US 2017/0034946 A1
(43) Pub. Date: Feb. 2, 2017

(54) SERVER EMBEDDED STORAGE DEVICE

(71) Applicant: SILICON GRAPHICS INTERNATIONAL CORP., MILPITAS, CA (US)

(72) Inventors: Eng Lim Goh, Singapore (SG); John Kichury, Morris Plains, NJ (US); Lance Evans, Boulder, CO (US)

(21) Appl. No.: 15/222,581

(22) Filed: Jul. 28, 2016

Related U.S. Application Data
(62) Division of application No. 14/565,084, filed on Dec. 9, 2014.
(60) Provisional application No. 61/913,901, filed on Dec. 9, 2013.

(51) Int. Cl. H05K 7/14; G06F 13/10

(52) U.S. Cl. CPC H05K 7/1498; H05K 7/1487; G06F 13/102

(57) ABSTRACT

A server is implemented within disk drive device or other drive device. The server-drive device may be used within a server tray having many disk drive devices, along with multiple other server trays in a cabinet of trays. One or more disk drive devices may be implemented in a server tray. The server-drive device may also be used in other applications. By implementing the server within the disk drive, valuable space is saved in a computing device.

### REFERENCE TO RELATED APPLICATIONS

This application is a divisional and claims the priority benefit of U.S. patent application Ser. No. 14/565,084 filed Dec. 9, 2014, which claims the priority benefit of U.S. provisional application No. 61/913,901 filed Dec. 9, 2013, the disclosures of which are incorporated herein by reference.

### BACKGROUND

1. Field of the Invention

The present invention generally relates to a data storage system. More specifically, the present invention relates to intelligent disk drive systems.

2. Description of the Related Art

The modern data center consists of many racks of server trays, wherein each tray includes several disk drives and a server. The server is a powerful, multi-core processor that manages communications between the disk drives and the outside environment.

One drawback of including a server device in a tray is that the server takes up valuable physical space within the tray. As customers demand more processing in less space, space within a rack has become very valuable and crucial to implementing racks that have the most space with the fastest processing.

What is needed is an improved rack that allows for more disk drive space while maintaining data handling efficiency.

### SUMMARY

The present technology implements a server within a 3.5 inch disk drive device or other nonvolatile data storage device. The server-drive device may be used within a server tray having many such devices, along with multiple other server trays in a cabinet of trays. One or more disk drive devices may be implemented in a server tray. The server-drive device may also be used in other applications. By implementing the server within the disk drive, valuable space is saved in a computing device.

The server-drive may include one or more cores, an operating system, and application software acting as a consumer or server of data, such as a Hadoop server. Within a tray of multiple drives, for example twenty or more drives, each and every drive will include the server with its own operating system. As a result, there is no need for a single server that does not store any data within a tray yet requires valuable physical space within the tray.

An embodiment may include an apparatus having a memory, processor, I/O port and housing. The processor executes code stored in the memory to implement a server. The I/O port is in communication with the memory device and the processor. The housing contains the memory device and the processor. The apparatus may be placed in a tray as one of a plurality of disk drives within the tray, wherein each disk drive includes its own server and operating system.

An embodiment may include a tray of storage devices. The tray may include a housing, a plurality of slots, and a plurality of storage devices. The plurality of slots may each receive a storage device. Each of the plurality of storage devices includes a processor, memory and a server, wherein the server includes an operating system.

### BRIEF DESCRIPTION OF THE DRAWINGS

FIG. 1 illustrates a server tray of the prior art.

FIG. 2 illustrates a server tray implemented using a server-drive.

FIG. 3 is a block diagram of a server within a disk drive.

FIG. 4 illustrates a computing device which may be used to implement the present technology.

### DETAILED DESCRIPTION

The present technology implements a server within a 3.5 inch disk drive device or other nonvolatile data storage device. The server-drive device may be used within a server tray having many such devices, along with multiple other server trays in a cabinet of trays. One or more disk drive devices may be implemented in a server tray. The server-drive device may also be used in other applications.

The server-drive may include one or more cores, an operating system, and a server such as a Hadoop server. Within a tray of multiple drives, for example twenty or more drives, each and every drive will include the server with its own operating system. As a result, there is no need for a single server that does not store any data within a tray yet requires valuable physical space within the tray.

The present technology improves storage density within a rack and allows for ease of application implementation, similar to how the innovation of SoC—Systems on a Chip—provides advantages for ease of implementing mobile applications. With all needed components in one disk-drive form-factor, a Hadoop server, for example, can be implemented as is on a disk drive of the present technology. In fact, the server of the present technology may be implemented as a system on a chip (SoC). Further, the server within a disk drive technology is scalable simply be adding additional all-in-one disk drive units to the rack and connecting them via a GigE/10 GigE switch.

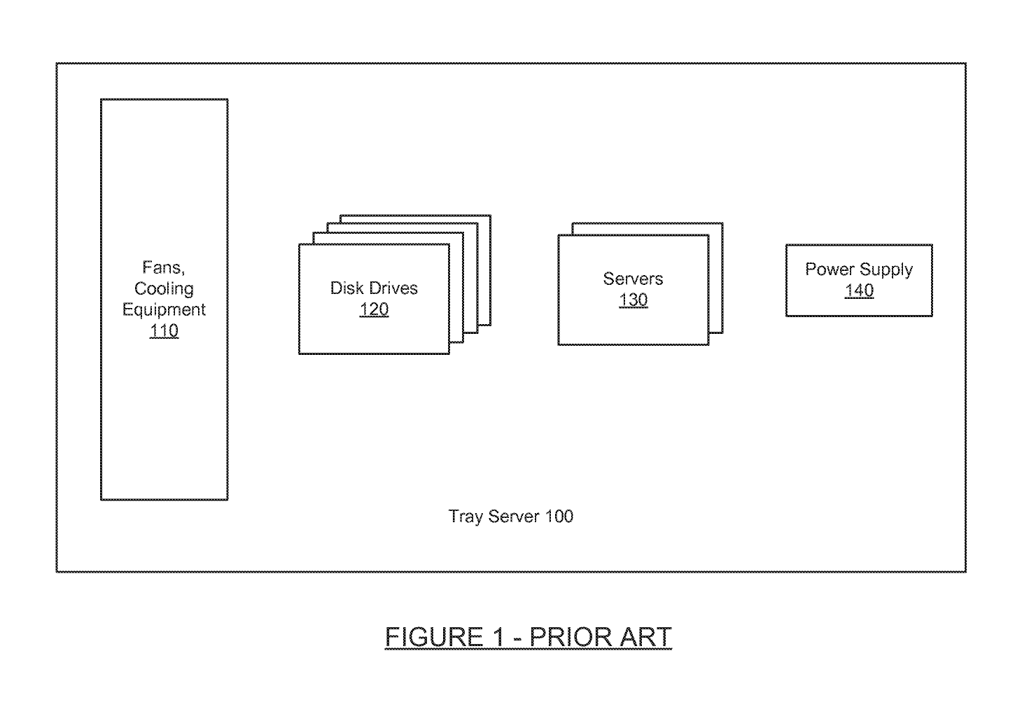

FIG. 1 illustrates a server tray of the prior art. Tray server 100 includes fans and cooling equipment 110, disk drives 120, servers 130, and power supply 140. Other components may be included within tray server 100, but are not illustrated for purposes of simplicity. The server tray 100 of the prior art includes a plurality of disk drive devices 120 and one or more server devices 130. The servers 130 are implemented separately, both in hardware and software, from the disk drive devices 120. Each server may include an I/O device, receive power from power supply 140

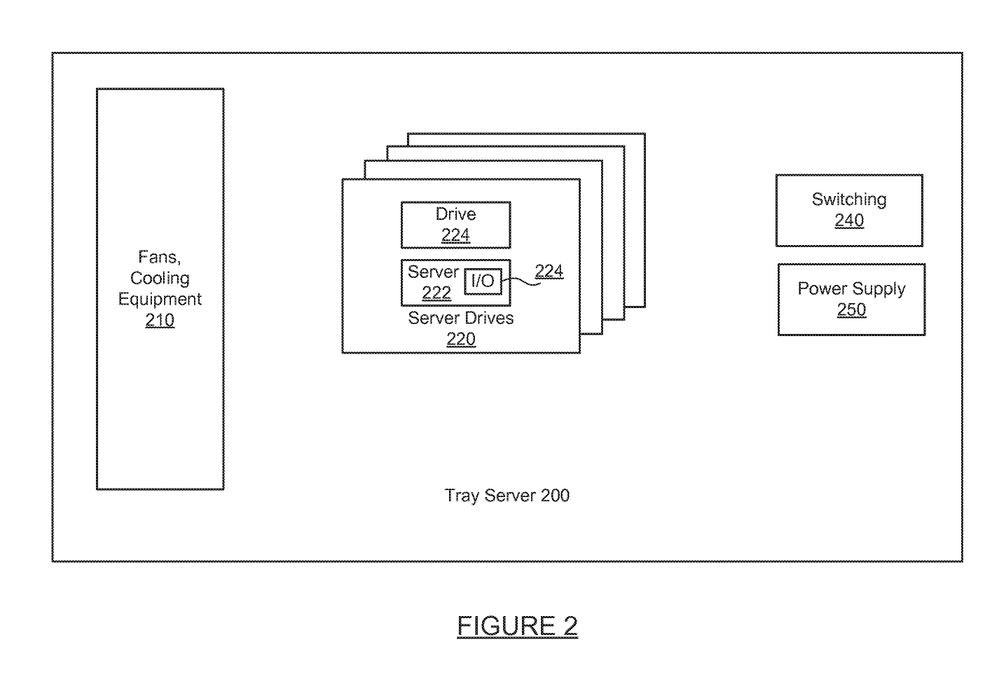

FIG. 2 illustrates a server tray implemented using a plurality of server-drives. Tray server 200 include fans and cooling equipment 210, server drives 220, switching 140, and power supply 150 The device of FIG. 2 may include a frame for containing the components of FIG. 2, for example a plurality of three and half inch disk drive slots. Each sever drive may include one or more servers 222 and one or more drives 224. The server drive of the present technology implements a server within a disk drive device 220. By implementing the server within the disk drive, valuable space is saved in a computing device.

Though not shown, each server drive may include a housing that is received by tray server 200 for installation of server drive 220 within the tray.

The server-drive device of the present technology may include one or more ports for external communication with or among a plurality of embedded servers within the server drives. The one or more ports may include an Ethernet Port as well as other ports for communicating over a network such as the Internet or other WAN, a LAN, intranet, extranet, private network, Wi-Fi network, cellular network or other network or networks. The Ethernet port may be used to communicate with the server as well as the disk drive. An Ethernet port may be used in place of or in addition to a typical SATA/SAS interface for the disk drive device. The sever drive may be accessed as a single node having a server and a drive.

Each server 22 may include its own I/O 224. Each I/O may communicate with a device or system external to the server 200 via switching circuitry 240.

The server may be implemented as a nano-server, micro server, or other server. In some instances, the server may be implemented as a system on a chip (SOC). The server hardware may include one or more processors. For example, one or more ARM processors may be used to implement the server within the server-drive device. One or more of the ARM processors may have one or multiple cores and may include SATA interfaces for communicating with the disk drive and other devices. Each server may include software provided by the device manufacturer or producer as well as allow users of the software (for example, entities that provide storage solutions to third party companies) to install and maintain applications on the server. Any number of disk drives within a computing device, server tray, or other machine may include a server. For example, in a server tray, a ratio of disk drives may be implemented as server-drive devices, such as for example 4 to 1 or some other ratio, such that the server in a particular disk drive may manage and communicate with four external disk drives.

In some embodiments, the server-drive device may include solid state drives. The solid state drives may be implemented with a server within the same device.

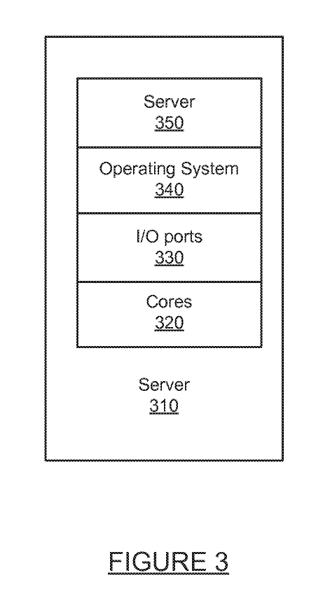

FIG. 3 is a block diagram of a server within a disk drive. The server 310 of FIG. 3 provides more detail for an embodiment of server 222 in the tray server of FIG. 2. Server 310 includes one or more cores 320, one or more I/O ports 330, an operating system 340, and a server s350.

For each tray having multiple drives, for example twenty or more drives, each and every drive will include a server with its own operating system (OS). As a result, there is no need for a single server that does not store any data within a tray yet requires valuable physical space within the tray. The OS may be one that is able to manage data access and manage the disk drive. For example, the OS may be implemented as a Linux, Windows, BSD, or other type of operating system.

The operating system may handle sending and receiving data over the I/O ports 330. The data may be stored in the server drive as a part of an array of servers within the tray.

When the server 310 includes multiple cores, the cores may perform different tasks. For example, if the cores 320 are implemented as a dual core ARM processor, one core may execute the server operating system while the other core implements a server. The server may be one of any suitable servers, such as a for example a Hadoop server.

Server 310 may include additional elements customary for such servers but not explicitly discussed herein, such as for example one or more processors, memory, and other components typical of a server

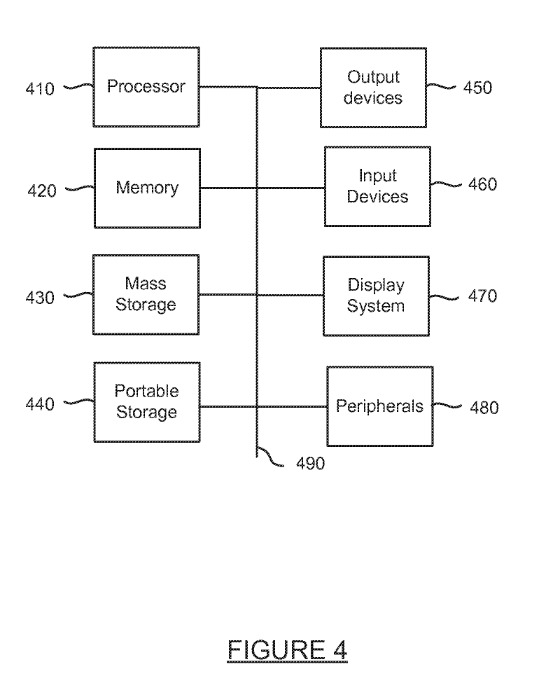

FIG. 4 illustrates an exemplary computing system 400 that may be used to implement all or a portion of a device for use with the present technology, such as for example tray server 200. The computing system 400 of FIG. 4 includes one or more processors 410 and memory 420. Main memory 420 stores, in part, instructions and data for execution by processor 410. Main memory 420 can store the executable code when in operation. The system 400 of FIG. 4 further includes a mass storage device 430, portable storage medium drive(s) 440, output devices 450, user input devices 460, a graphics display 470, and peripheral devices 480.

The components shown in FIG. 4 are depicted as being connected via a single bus 490. However, the components may be connected through one or more data transport means. For example, processor unit 410 and main memory 420 may be connected via a local microprocessor bus, and the mass storage device 430, peripheral device(s) 480, portable storage device 440, and display system 470 may be connected via one or more input/output (I/O) buses.

Mass storage device 430, which may be implemented with a magnetic disk drive, solid state drives, an optical disk drive or other devices, may be a non-volatile storage device for storing data and instructions for use by processor unit 410. Mass storage device 430 can store the system software for implementing embodiments of the present invention for purposes of loading that software into main memory 420.

Portable storage device 440 operates in conjunction with a portable non-volatile storage medium, such as a floppy disk, compact disk or Digital video disc, to input and output data and code to and from the computer system 400 of FIG. 4. The system software for implementing embodiments of the present invention may be stored on such a portable medium and input to the computer system 400 via the portable storage device 440.

Input devices 460 provide a portion of a user interface. Input devices 460 may include an alpha-numeric keypad, such as a keyboard, for inputting alpha-numeric and other information, or a pointing device, such as a mouse, a trackball, stylus, or cursor direction keys. Additionally, the system 400 as shown in FIG. 4 includes output devices 450. Examples of suitable output devices include speakers, printers, network interfaces, and monitors.

Display system 470 may include a liquid crystal display (LCD) or other suitable display device. Display system 470 receives textual and graphical information, and processes the information for output to the display device.

Peripherals 480 may include any type of computer support device to add additional functionality to the computer system. For example, peripheral device(s) 480 may include a modem or a router.

The components contained in the computer system 400 of FIG. 4 are those typically found in computer systems that may be suitable for use with embodiments of the present invention and are intended to represent a broad category of such computer components that are well known in the art. Thus, the computer system 400 of FIG. 4 can be a personal computer, hand held computing device, telephone, mobile computing device, workstation, server, minicomputer, mainframe computer, or any other computing device. The computer can also include different bus configurations, networked platforms, multi-processor platforms, etc. Various operating systems can be used including Unix, Linux, Windows, Macintosh OS, Android, and other suitable operating systems.

The foregoing detailed description of the technology herein has been presented for purposes of illustration and description. It is not intended to be exhaustive or to limit the technology to the precise form disclosed. Many modifications and variations are possible in light of the above teaching. The described embodiments were chosen in order to best explain the principles of the technology and its practical application to thereby enable others skilled in the art to best utilize the technology in various embodiments and with various modifications as are suited to the particular use contemplated. It is intended that the scope of the technology be defined by the claims appended hereto.

1-2. (canceled)

3. A method for scaling data storage, the method comprising:
providing a plurality of devices for storing and serving data, wherein each of the plurality of devices for storing and serving data include:
a non-volatile storage device,
a memory,
a multi-core processor that executes code stored in the memory when storing and serving the data,
one or more I/O ports,
a housing containing the non-volatile storage device, the memory, and the processor, wherein the one or more I/O ports communicate the data to a number of additional non-volatile data storages device of a plurality of additional non-volatile data storage devices; and
identifying a server-drive ratio, wherein the server-drive ratio corresponds to the number of additional non-volatile data storage devices of a plurality of non-volatile data storage devices that connect to each housing via the one or more I/O ports of each housing, and each the plurality of non-volatile data storage devices are connected to the one or more I/O ports of each housing according to the server-drive ratio.

4. The method of claim 3, wherein the plurality of devices are displaced within a tray.

5. The method of claim 4, wherein the tray is one of a plurality of trays included in a cabinet.

6. The method of claim 4, wherein each of the additional data storage devices are displaced within the tray.

7. The method of claim 6, wherein the tray is one of a plurality of a plurality of trays included in a cabinet.

8. The method of claim 3, wherein each of the plurality of devices are connected to each other via switching circuitry.

9. The method of claim 8, wherein the switching circuitry is a GigE/10 GigE switch.

10. The method of claim 3, wherein each of the one or more I/O ports are connected to the number of additional non-volatile data storage devices via switching circuitry.

11. The method of claim 10, wherein the switching circuitry is a GigE/10 GigE switch.

12. The method of claim 1, wherein the non-volatile storage device of the plurality of devices for storing and serving data include a non-volatile solid state memory.

13. The method of claim 1, wherein the plurality of additional non-volatile data storage devices include a non-volatile solid state memory.

14. The method of claim 1, wherein the housing is suitable for implementing a three and a half inch, two and a half inch, 1.8 inch, or M.2 type disk drive device.

15. The method of claim 1, wherein each of the plurality of devices include operating system software.

16. The method of claim 15, wherein the operating system software is at least one of Linux, Windows or BSD operating system.

17. The method of claim 1, wherein the multi-core processor and the memory are included in a system on a chip.

18. The method of claim 4, wherein the tray includes a plurality of slots for receiving each housing of the plurality of devices.
